(19) United States
(12) Patent Application Publication
(10) Pub. No.: US 2025/0006575 A1
(43) Pub. Date: Jan. 2, 2025

(54) SEMICONDUCTOR PACKAGE WITH COVERED MAGNETIC MOLD COMPOUND

(71) Applicant: TEXAS INSTRUMENTS INCORPORATED, Dallas, TX (US)

(72) Inventors: Daiki Komatsu, Oita-Pref (JP); Hidetoshi Inoue, Tokyo (JP)

(21) Appl. No.: 18/217,504

(22) Filed: Jun. 30, 2023

(51) Int. Cl. H01L 23/29; H01F 27/28; H01L 21/56; H01L 23/31; H01L 23/495; H01L 25/16

(52) U.S. Cl. CPC H01L 23/295; H01F 27/2804; H01L 21/56; H01L 23/3135; H01L 23/49541; H01L 25/165; H01L 28/10; H01L 28/40

(57) ABSTRACT

A semiconductor package includes a substrate, a semiconductor die, metal interconnects, the semiconductor die being mounted to the substrate via the metal interconnects, an inductor mounted to the substrate, a magnetic material encapsulating the semiconductor die, the inductor, and the metal interconnects, the magnetic material including metal particles suspended in a first insulation material, and a second insulation material covering the magnetic material, wherein the second insulation material is substantially free of metal particles.

### BACKGROUND

Electronic package technology continues trends towards miniaturization, integration, and speed. Semiconductor packages provide support for a semiconductor die, such as an integrated circuit (IC) chip, and associated internal electrical connections, provide protection from the environment, and enable surface-mounting of the die to and interconnection with an external component, such as a printed circuit board (PCB). Leadframe semiconductor packages are well known and widely used in the electronics industry to house, mount, and interconnect a variety of ICs.

A conventional leadframe is typically die-stamped from a sheet of flat-stock metal and includes a plurality of metal leads temporarily held together in a planar arrangement about a central region during package manufacture by siderails forming a rectangular frame. A mounting pad for a semiconductor die is supported in the central region by “tie-bars” that attach to the frame. The leads extend from a first end integral with the frame to an opposite second end adjacent to, but spaced apart from, the die pad. The die pad serves as a substrate providing a stable support for firmly positioning the semiconductor die within the semiconductor package during manufacturing, whereas the leads provide electrical connections from outside the package to the active surface of the semiconductor die. Gaps between the inner end of the leads and contact pads on the active surface of the semiconductor die are bridged by connectors, typically wire bonds-thin metal wires individually bonded to both the contact pads and the leads.

As alternatives to a conventional leadframe, routable leadframes include at least one metal layer supported by a dielectric layers, such as laminate films and/or premolded dielectric layers. The routable leadframes may provide integrated connections between die contacts, other package components, and package leads—eliminating or reducing the need for wire bond connections.

Semiconductor packages may further include a mold compound covering the pad, the semiconductor die, wire bonds (if applicable), and portions of the leads. Such semiconductor packages may be created by a molding process, with a polymer compound, such as an epoxy formulation filled with inorganic granules, molded around an assembled semiconductor die and leadframe portions. In this process, a substrate with the attached and bonded semiconductor die is placed in the cavity of a steel mold. Viscous mold compound is pressured into the cavity to fill the cavity and surround the semiconductor die and leadframe portions without voids. After polymerizing the compound, for example, by cooling to ambient temperature, the mold is opened, while the mold compound remains adhered to the molded parts.

An inductor stores energy in a magnetic field when electric current flows through it, and provides an electric current by discharging the stored energy. Inductors have many applications, such as proximity sensing, energy storage, actuation, power transmission, and filtering. The inductor may be coupled to or can be part of semiconductor die, such as an integrated circuit, which includes circuitries that operate with the inductor to support those applications. In some examples, the inductor and the circuitries are enclosed in a semiconductor package, which can reduce the footprint of the package and shorten the interconnects between the inductor and the circuitries.

### SUMMARY

Semiconductor packages disclosed herein include magnetic mold compound covered by an insulation layer. The insulation layer may mitigate electrical shorts between exposed metal particles in the magnetic mold compound and between the magnetic mold compound and adjacent components of an electronic device.

In one example, a semiconductor package includes a substrate, a semiconductor die, metal interconnects, the semiconductor die being mounted to the substrate via the metal interconnects, an inductor mounted to the substrate, a magnetic material encapsulating the semiconductor die, the inductor, and the metal interconnects, the magnetic material including metal particles suspended in a first insulation material, and a second insulation material covering the magnetic material, wherein the second insulation material is substantially free of metal particles.

In another example a method includes mounting semiconductor dies to a substrate, mounting inductors to the substrate, molding a magnetic material over the semiconductor dies and the inductors, the magnetic material including metal particles suspended in a first insulation material, cutting the magnetic material to form grooves between adjacent semiconductor dies, wherein the substrate remains intact subsequent to cutting the magnetic material, covering exposed surfaces of the magnetic material with a second insulation material, and dicing the substrate to form semiconductor packages including respective semiconductor dies and inductors.

### BRIEF DESCRIPTION OF THE DRAWINGS

FIGS. 1A and 1B are schematic diagrams of an example semiconductor die.

FIG. 2A, FIG. 2B, FIGS. 3A-3C, and FIGS. 4A-4C are schematic diagrams of examples of a semiconductor die.

FIG. 5A, FIG. 5B, and FIG. 5C are schematic diagrams illustrating the structure of an example magnetic material of a semiconductor package.

FIG. 6A and FIG. 6B are schematic diagrams illustrating the structure of another example magnetic material of a semiconductor package.

FIG. 7 is a flowchart of an example method of creating a magnetic material.

FIG. 8 is a schematic diagram illustrating the structure of another example semiconductor package including an insulation layer covering the magnetic material of the semiconductor package.

FIG. 9 is a flowchart of an example method of fabricating a semiconductor package including an insulation layer covering the magnetic material of the semiconductor package

FIGS. 10A-10I are schematic diagrams that illustrate various operations of the example method of FIG. 9.

### DETAILED DESCRIPTION

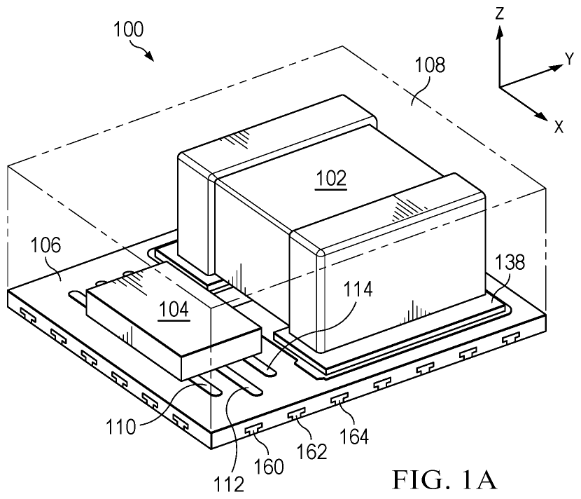

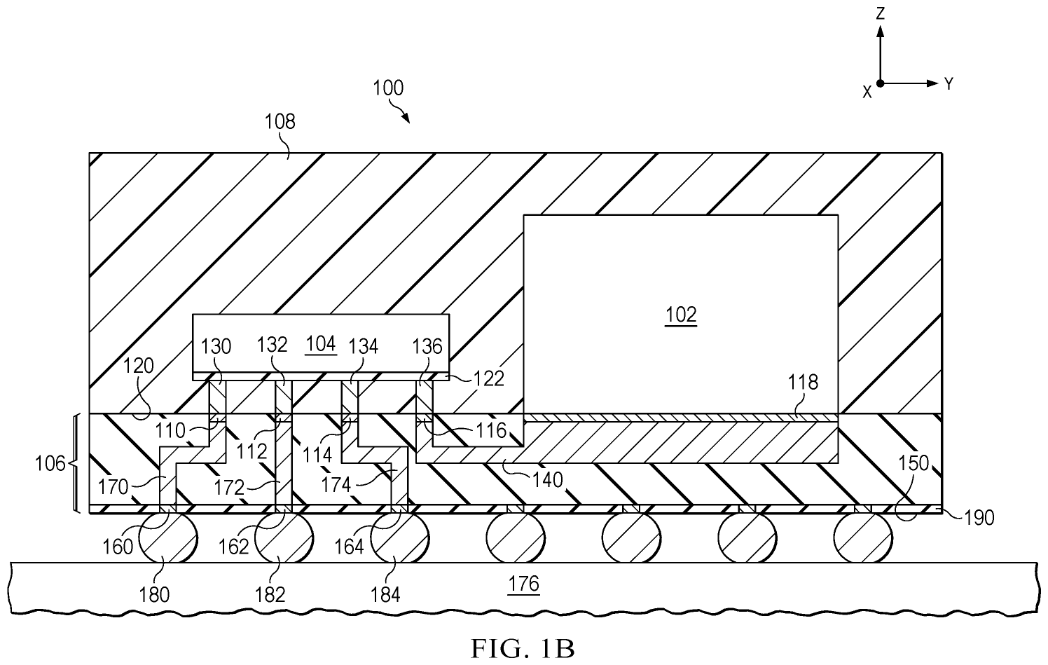

FIG. 1A and FIG. 1B are schematic diagrams that illustrate an example semiconductor package 100. FIG. 1A and FIG. 1B illustrate, respectively, a perspective view and a side view of semiconductor package 100. Referring to FIG. 1A and FIG. 1B, semiconductor package 100 includes an inductor 102 and a semiconductor die 104 mounted to a package substrate 106 and encapsulated in a mold compound 108. Inductor 102 includes metal coils surrounding a core. Examples of an inductor core includes an air core, a ferrite core, or a metal particle core. The inductor 102 can also be a molded inductor, in which the coils and the core are encapsulated in a package made of a molding compound, such as a magnetic molding compound (MMC) having metallic particles (e.g., iron particles) and an insulation material (e.g., a polymer resin) in which the metallic particles are suspended. Mold compound 108 can shield the coils and the core and increase the magnetic field density, which can improve the efficiency of inductor 102 in converting between electrical and magnetic energies. In various examples, mold compound 108 may be an epoxy molding compound (EMC), that can electrically insulate inductor 102 and semiconductor die 104 from external electrical signals, such as noise signals and electrostatic signals.

The MMC resin may include epoxy resins, polyurethane resins, and/or silicone resins. The resin may further include, in addition to metal particles, one or more of the following: hardener, curing agent, fused silica, inorganic fillers, catalyst, flame retardants, stress modifiers, adhesion promoters, and other suitable components. Fillers, if any, may be selected to modify properties and characteristics of the resin base materials. Inert inorganic fillers may be selected to lower a coefficient of thermal expansion (to match semiconductor die 104), increase thermal conductivity (e.g., nonmetallic fillers, such as ceramic particles), and/or increase clastic modulus of mold compound 108 compared to the resin base. Particulate fillers may be selected to reduce strength characteristics such as tensile strength and flexural strength compared to the resin base materials. In some examples, the MMC may include 90-98 percent by weight metal filler, 2-9 percent by weight Epoxy/Phenol resin, 0-3 percent by weight additives, such as wax, curing accelerator, and/or silane coupling agent. In some particular examples, the MMC may include 95-96 percent by weight metal filler, 3-4 percent by weight Epoxy/Phenol resin, and about 1 percent by weight additives, such as wax, curing accelerator, and/or silane coupling agent. In some of such examples, the metal fillers may be an alloy like a Fe—Si—Cr—B, Fe—Si—Cr—B—Cu, with amorphous particles, not crystalline.

Semiconductor die 104 and inductor 102 can form a system to support a particular application, such as proximity sensing, energy storage, actuation, power transmission, and filtering. For example, semiconductor package 100 includes a proximity sensor, in which semiconductor die 104 includes an oscillator and a sensing circuit. The oscillator can drive inductor 102 with an oscillating current signal, and the sensing circuit can sense the frequency of the current signal. A metal object approaching inductor 102 can change the inductance of inductor 102, which can change the frequency of the current signal. The sensing circuit can detect the metal object by detecting the frequency change. As another example, semiconductor package 100 includes a switch-mode power converter to transmit power from a power source to a load. In such example, inductor 102 can provide energy storage, and semiconductor die 104 includes switches to charge and discharge the inductor 102 to set the voltage across the load.

Package substrate 106 provides mechanical support to inductor 102 and semiconductor die 104, and provides electrical connections between the inductor and the semiconductor die, and electrical connections to between semiconductor package 100 and an external device. In this manner package substrate 106 may be a routable leadframe. For example, package substrate 106 includes an electrical insulation material, such as a polymer, an Ajinomoto Build-up Film (ABF), or a ceramic material. Package substrate 106 also includes metal pads 110, 112, 114, 116, and 118, which can be copper pads, on a surface 120 to which inductor 102 and semiconductor die 104 are mounted.

Also, semiconductor die 104 includes a passivation layer 122, which is coupled to metal pads 110, 112, 114, and 116 via respective metal interconnects 130, 132, 134, and 136. Each pad is coupled to a respective metal interconnect via a solder layer. Passivation layer 122 can insulate circuitries in semiconductor die 104 from metal interconnects 130, 132, 134, and 136. Metal interconnects 130 through 136 includes, for example, copper pillars, solder bumps, and under bump metallization (UBM) interconnects. Also, inductor 102 is coupled to metal pad 118 via a solder layer. Package substrate 106 includes metal interconnects on or under surface 120 to provide electrical connections between inductor 102 and semiconductor die 104, such as metal interconnect 140 between metal pads 116 and 118.

Package substrate 106 also includes metal pads on a surface 150 opposite to surface 120, such as metal pads 160, 162, and 164 which includes copper pads or pads made of other metals (e.g., silver or palladium). Package substrate 106 also includes metal interconnects, such as copper interconnects, to provide electrical connections between metal pads on the opposite surfaces. For example, package substrate 106 includes metal interconnect 170 between metal pads 110 and 160, metal interconnect 172 between metal pads 112 and 162, and metal interconnect 174 between metal pads 114 and 164. The metal pads on surface 150 and the interconnects can provide electrical connections between an external device and semiconductor package 100. For example, metal pads 160, 162, and 164 are coupled to a printed circuit board (PCB) 176 via respective solder balls 180, 182, and 184, which can provide electrical connections between semiconductor package 100 and an external device (e.g., a power source) on PCB 176. Package substrate 106 also includes a solder resist layer 190 on surface 150 to shield metal interconnects in the package substrate (e.g., metal interconnects 170, 172, and 174) from the solder balls.

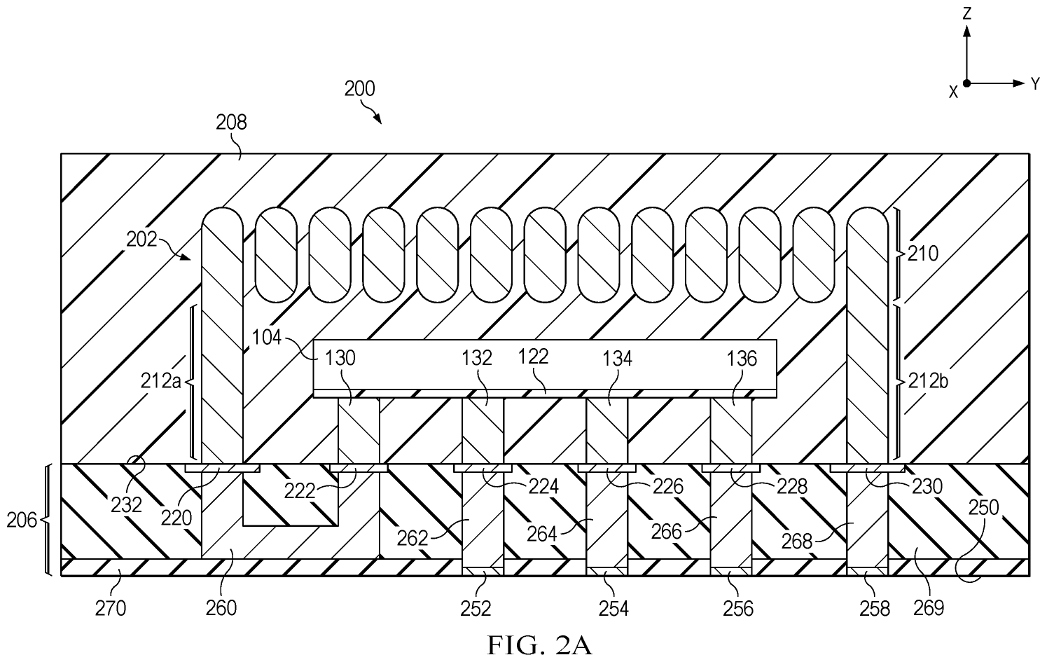

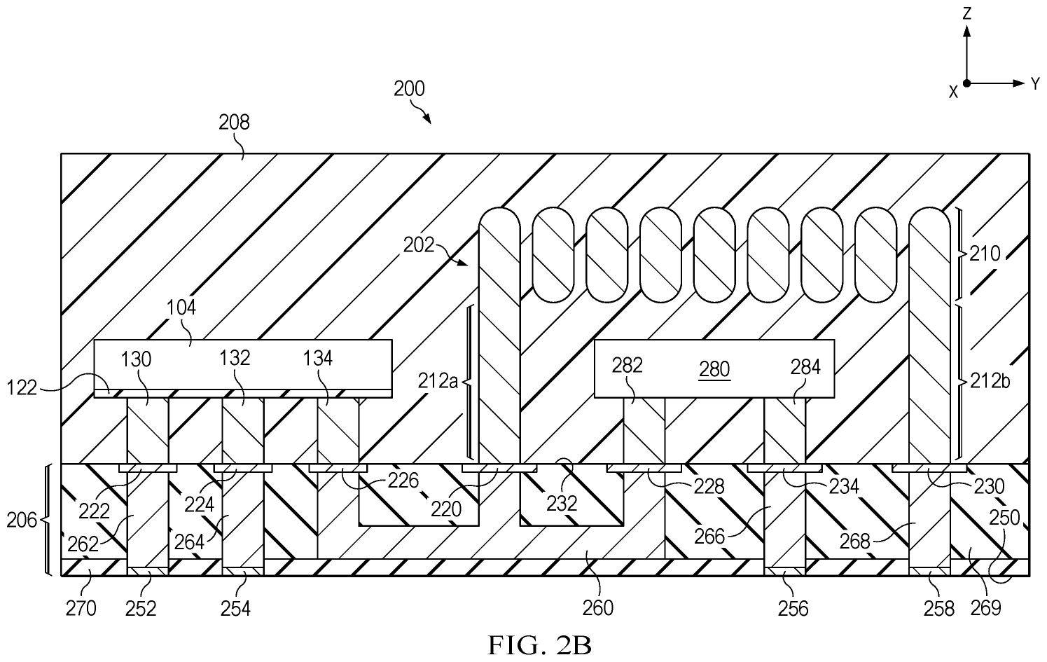

FIG. 2A illustrates an example of semiconductor package 200 that can have a reduced footprint compared with semiconductor package 100 of FIGS. 1A and 1B. FIG. 2A illustrates a side view of semiconductor package 200. Referring to FIG. 2A, semiconductor package 200 includes an inductor 202 and semiconductor die 104 mounted to package substrate 206. Semiconductor package 200 also includes a magnetic material (e.g., MMC) on package substrate 206. The magnetic material can encapsulate inductor 202 and semiconductor die 104 within semiconductor package 200. In some examples, package substrate 206 includes a routable lead frame (RLF). Inductor 202 includes a coil portion 210, which includes various types of cores such as a ferrite core and a metal particle core, and stilt portions 212a and 212b that support coil portion 210 over package substrate 206. Also, semiconductor die 104 is positioned between stilt portions 212a and 212b and underneath coil portion 210, so that coil portion 210 and semiconductor die 104 can form a device stack. In some examples, coil portion 210 can have openings facing sideways (e.g., along the x/y axes), as shown in FIGS. 3A-3C. In some examples, coil portion 210 can have openings facing up/down over semiconductor die 104 (e.g., along the z-axis), as shown in FIGS. 4A-4C.

Package substrate 206 includes metal pads 220, 222, 224, 226, 228, and 230, which can be copper pads, on a surface 232 on which inductor 202 and semiconductor die 104 are attached. Semiconductor package 200 includes metal interconnects 130, 132, 134, and 136 of semiconductor die 104 coupled to respective metal pads 222, 224, 226, and 228 via a solder layer. Also, stilt portions 212a and 212b of inductor 202 are coupled to respective metal pads 220 and 230 via a solder layer.

Package substrate 206 also includes metal pads on a surface 250 opposite to surface 232, such as metal pads 252, 254, 256, and 258 which includes copper pads or pads made of other metals (e.g., silver and palladium). Metal pads 252, 254, 256, and 258 are coupled to an external device via solder balls, such as PCB 176 and solder balls 180 through 184 of FIG. 1B, to provide electrical connections between semiconductor package 200 and the external device. Package substrate 206 further includes metal interconnects, such as copper interconnects, that connect between the metal pads of the same or different surfaces. For example, package substrate 206 includes a metal interconnect 260 coupled between metal pads 220 and 222 (on surface 232) to provide an electrical connection between inductor 202 and semiconductor die 104. Package substrate 206 also includes a metal interconnect 262 coupled between metal pads 224 and 252, a metal interconnect 264 coupled between metal pads 226 and 254, a metal interconnect 266 coupled between metal pads 228 and 256, and a metal interconnect 268 coupled between metal pads 230 and 258, to provide electrical connections between the external device and inductor 202 and/or semiconductor die 104.

Package substrate 206 includes an electrical insulation layer 269, such as a polymer, ABF, or a ceramic material, to provide electrical insulation among the metal interconnects and the metal pads. Also, package substrate 206 includes a solder resist layer 270 below surface 250 to shield metal interconnects in the package substrate (e.g., metal interconnects 260, 262, 264, 266, and 268) from the solder balls and the external device.

Also, as described above, inductor 202 and semiconductor die 104 are encapsulated in mold compound 208 on package substrate 206. Mold compound 208 includes a magnetic material such as an MMC. The MMC can have metallic particles (e.g., iron particles) and an insulation material (e.g., a polymer resin) in which the metallic particles are suspended. Mold compound 208 shields inductor 202 and increases the magnetic field density, which can improve the efficiency of inductor 202 in converting between electrical and magnetic energies. The MMC material of mold compound 208 can fill the space within inductor 202, such as in the center of coil portion 210 (e.g., if inductor 202 has an air core) and between individual coils of coil portion 210. The MMC material can also fill the space between coil portion 210 and semiconductor die 104, and between metal interconnects 130, 132, 134, and 136.

FIG. 2B illustrates another example of semiconductor package 200. Referring to FIG. 2B, semiconductor die 104 is positioned outside of and adjacent to inductor 202. Semiconductor package 200 includes another circuit component, such as a capacitor 280, positioned under coil portion 210 and stilt portions 212a and 212b, so that coil portion 210 and capacitor 280 can form a device stack. In some examples, semiconductor die 104 and capacitor 280 are positioned under coil portion 210 and stilt portions 212a and 212b to form the device stack.

Package substrate 206 includes metal pad 234 (e.g., copper pad) in addition to metal pads 220 through 230 on surface 232 on which semiconductor die 104 and capacitor 280 are attached. Semiconductor package 200 includes metal interconnects 130, 132, and 134 (e.g., copper pillars, solder bumps, or UBM interconnects) coupled between semiconductor die 104 and respective metal pads 222, 224, and 226 of package substrate 206. Also, semiconductor package 200 includes metal interconnects 282 and 284 (e.g., copper pillars, solder bumps, or UBM interconnects) coupled between capacitor 280 and respective metal pads 228 and 234. Package substrate 206 also includes metal interconnects coupled between metal pads on surface 232 and on surface 250 to provide external access to semiconductor die 104, inductor 202, and capacitor 280. For example, package substrate 206 includes metal interconnect 262 coupled between metal pads 222 and 252, metal interconnect 264 coupled between metal pads 224 and 254, metal interconnect 266 coupled between metal pads 234 and 256, and metal interconnect 268 coupled between metal pads 230 and 258. Package substrate 206 also includes metal interconnect 260 coupled among metal pads 220, 226, and 228 to provide an internal electrical connection among semiconductor die 104, inductor 202, and capacitor 280.

By placing semiconductor die 104 and/or capacitor 280 below coil portion 210 of inductor 202, semiconductor package 200 of FIG. 2A and FIG. 2B can have a reduced footprint (e.g., on the x-y plane), which can also shorten the metal interconnects between semiconductor die 104 and inductor 202 (e.g., metal interconnect 260) and reduce their parasitic capacitances. The arrangements of FIG. 2A and FIG. 2B also allow the coil portion of the inductor to cover most of the footprint of semiconductor package 200, which facilitates a larger inductor with increased inductance can be included in semiconductor package 200. Also, by encapsulating inductor 202 in an MMC encapsulation package, the magnetic field density within semiconductor package 200 can be increased, which can improve the efficiency of inductor 202 in converting between electrical and magnetic energies.

Semiconductor package 200 can be fabricated by mounting multiple electronic components (e.g., semiconductor dies 104, inductors 202 and/or capacitors 280) to a substrate, depositing an MMC material onto the electronic components and the substrate, molding and hardening the MMC material to form an encapsulation package, and then dicing the molded and hardened MMC material and the substrate into multiple semiconductor packages 200, such that each semiconductor package 200 includes a set of electronic components (e.g., a semiconductor die 104, an inductor 202 and/or a capacitor 280) mounted to substrate 206 and encapsulated by MMC material mold compound 208.

While the MMC material mold compound 208 can increase magnetic field density within semiconductor package 200, the dicing operation can change the structure of the MMC material on the diced surface and reduce the electrical breakdown voltage through the MMC material. Because of the reduced electrical breakdown voltage, a relatively small voltage difference between the metal interconnects can be sufficient for leakage current to flow between the metal interconnects through the MMC material, which can increase the risk of electrical shorts. Accordingly, the functionality, reliability, and safety of semiconductor package 200 can become compromised.

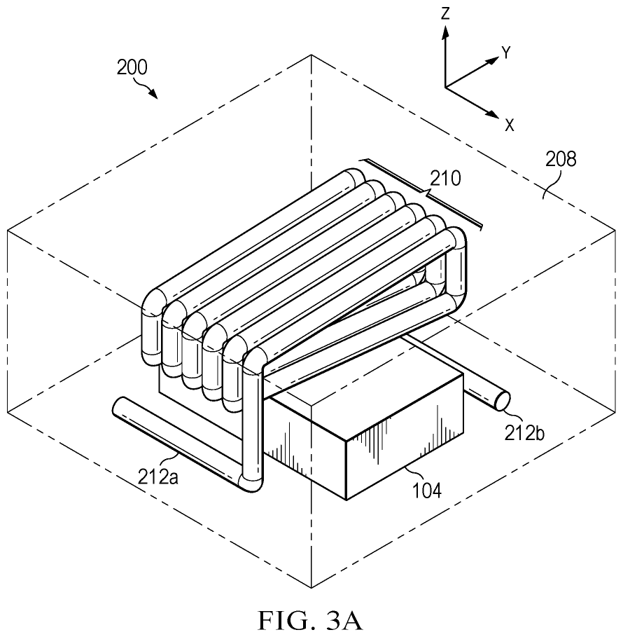

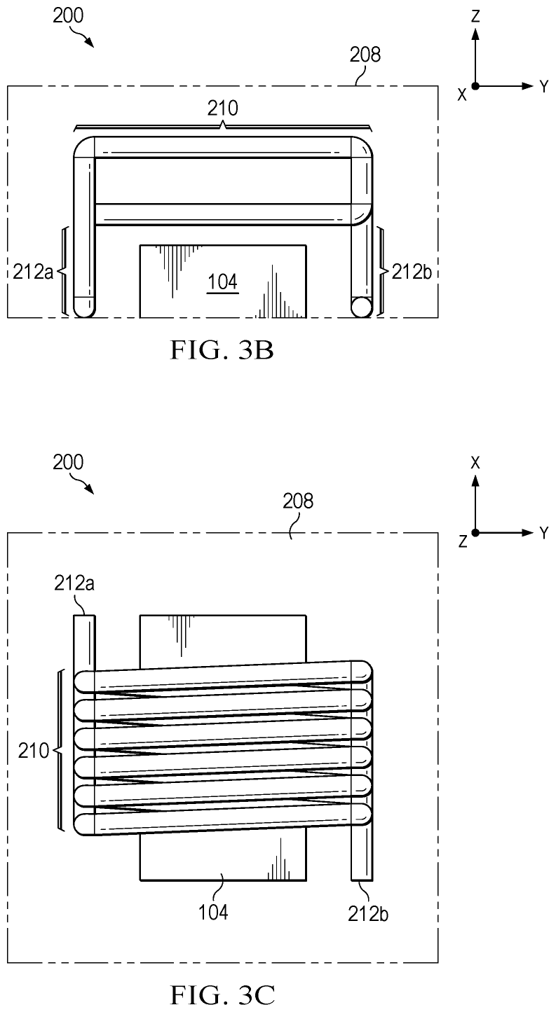

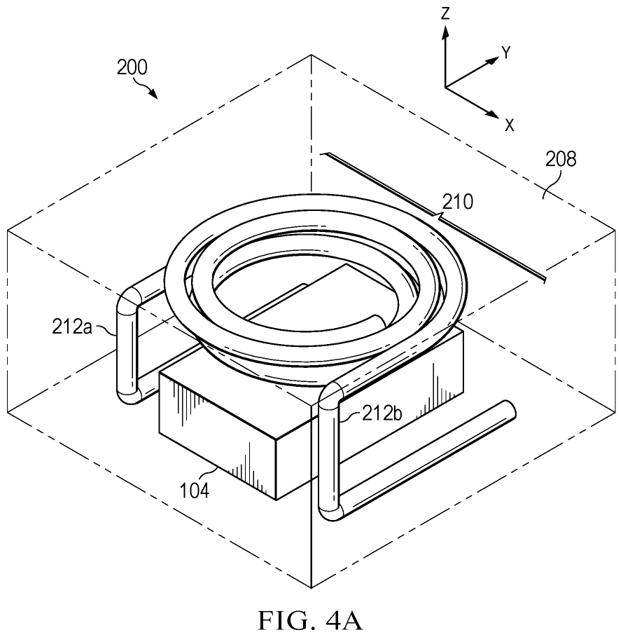

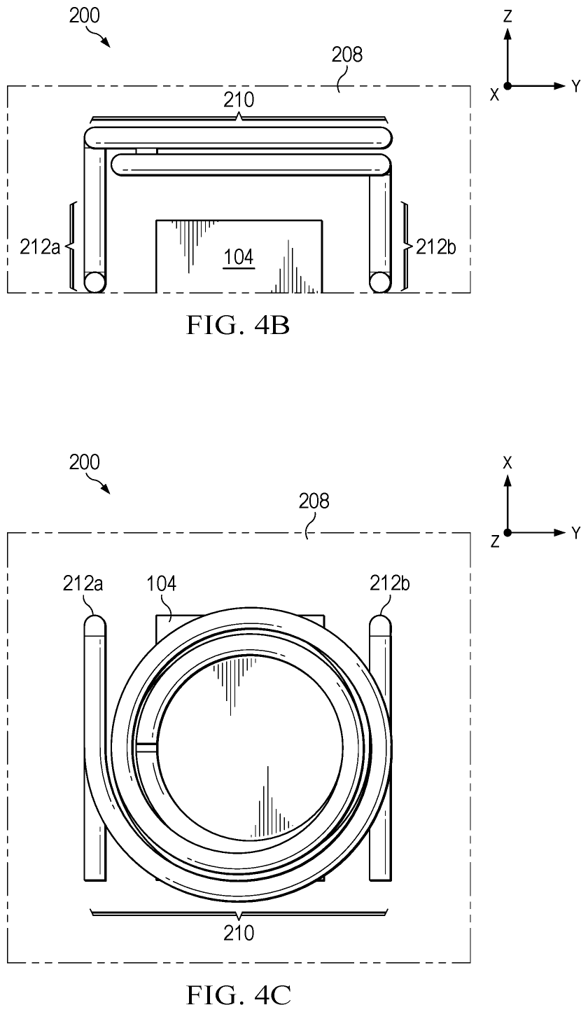

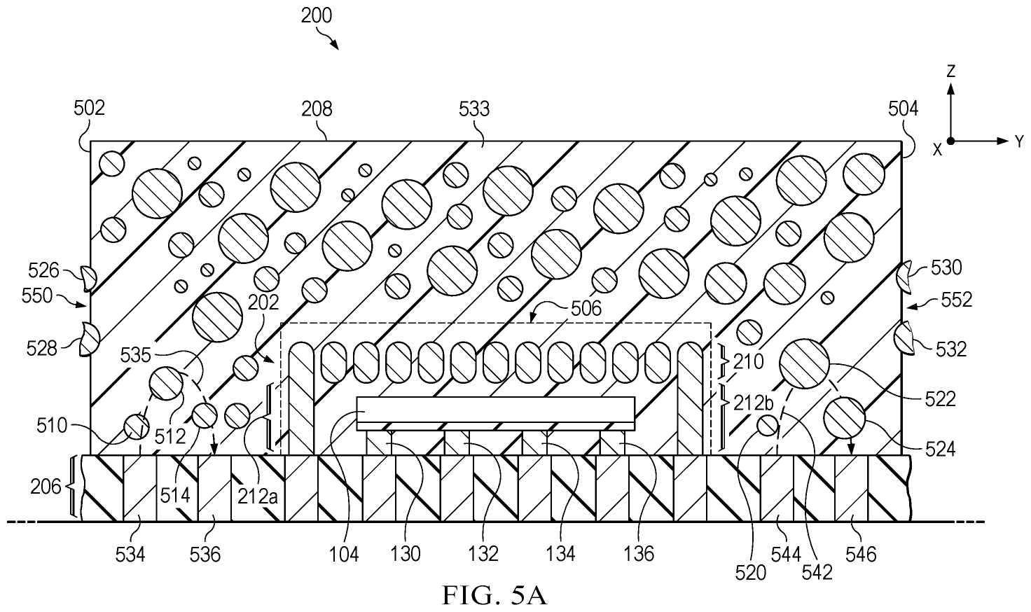

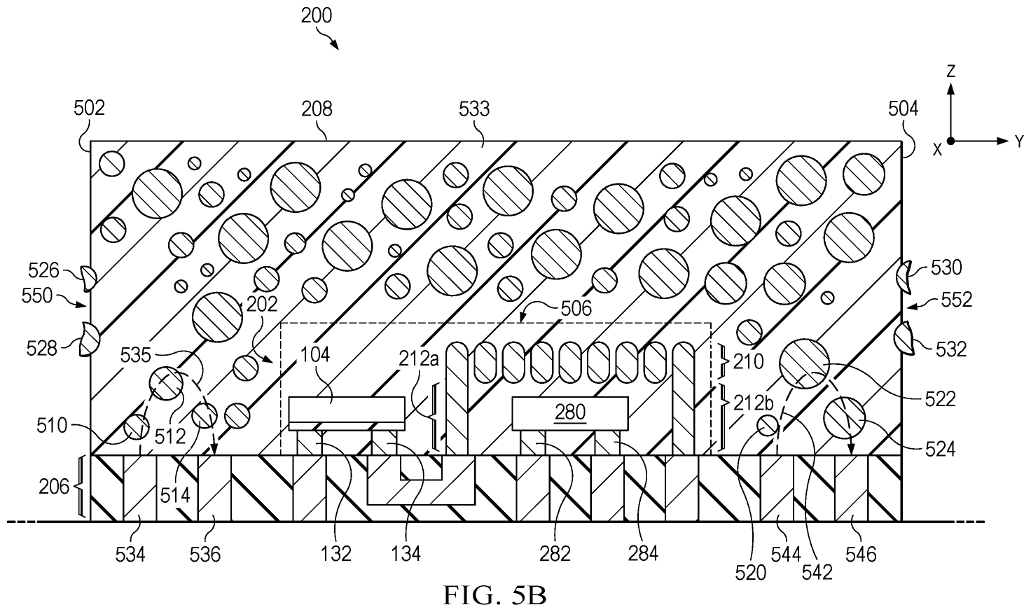

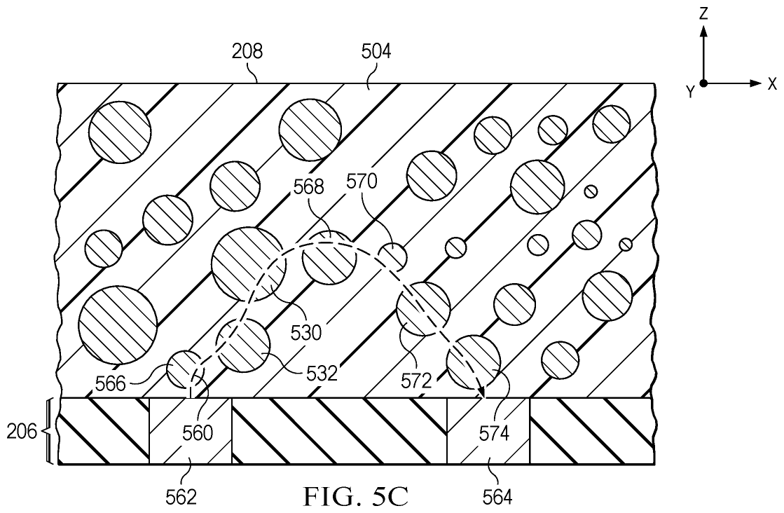

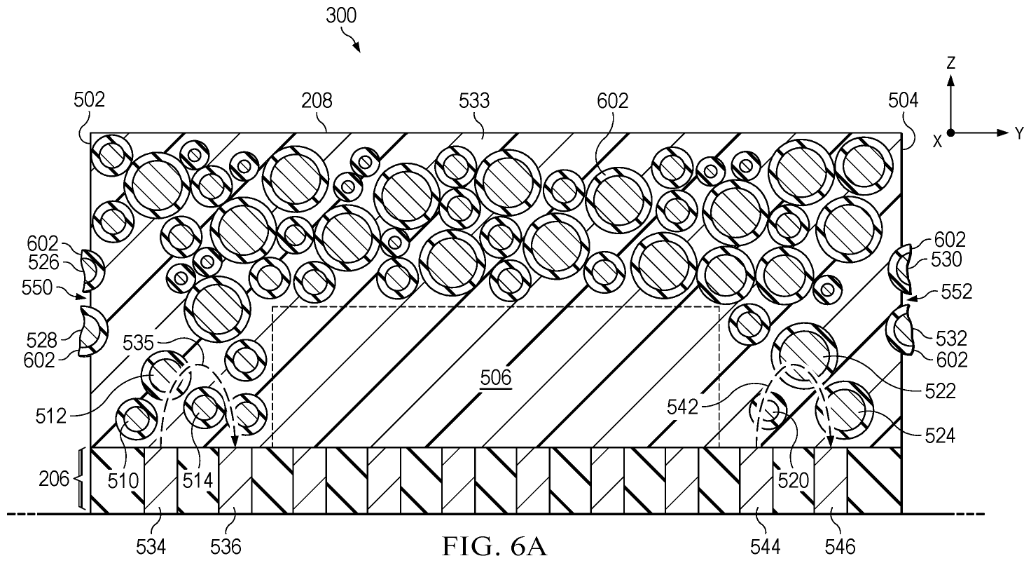

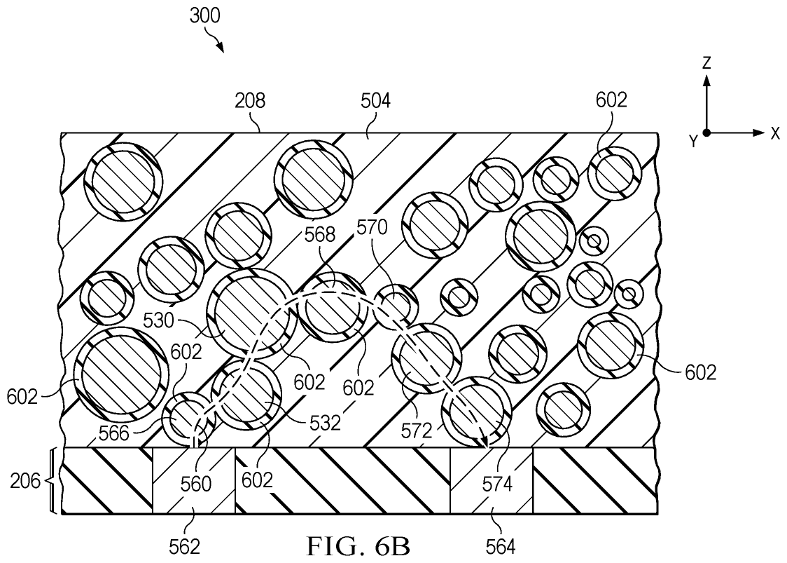

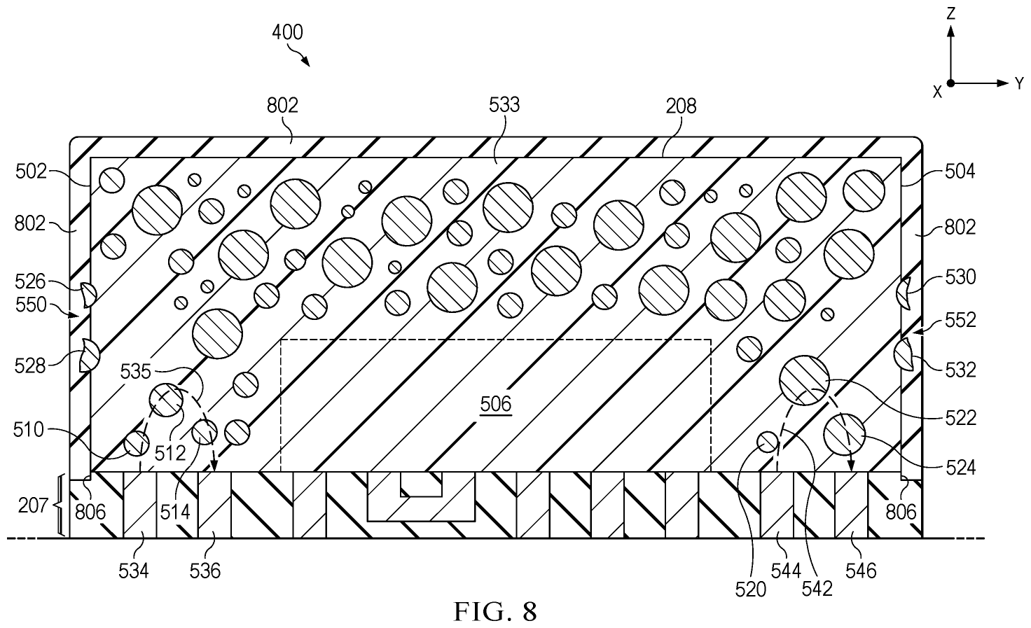

FIGS. 5A-5C are schematic diagrams that illustrate example structure of the MMC material of mold compound 208 of semiconductor package 200. FIG. 5A and FIG. 5B illustrates a first view of MMC material mold compound 208 and substrate 206 from the x-axis, where diced surfaces 502 and 504 are on the x-z plane. Also, FIG. 5C illustrates a second view of MMC material mold compound 208 and substrate 206 of FIG. 5A or FIG. 5B from the y-axis and including diced surface 502. MMC material mold compound 208 and substrate 206 encapsulate electronic devices 506. In the example of FIG. 5A, electronic devices 506 includes semiconductor die 104, inductor 202, and metal interconnects 130 through 136 of FIG. 2A, with semiconductor die 104 positioned between stilt portions 212a and 212b and below coil portion 210 of inductor 202. In the example of FIG. 5B, electronic devices 506 includes semiconductor die 104, inductor 202, capacitor 280, and metal interconnects 132, 134, 282, and 284 of FIG. 2B, with capacitor 280 positioned between stilt portions 212a and 212b and below coil portion 210 of inductor 202, and semiconductor die 104 positioned adjacent to inductor 202. In subsequent FIGS. 6A and 8, electronic devices 506 are represented by a dotted line box for brevity.

Referring to FIGS. 5A-FIG. 5C, the MMC material of mold compound 208 includes metal particles (e.g., iron particles), such as metal particles 510, 512, 514, 520, 522, 524, 526, 528, 530, and 532, suspended in epoxy resin 533, such as an epoxy-based thermoset polymer. In FIG. 5A, metal particles 510, 512, 514, 520, 522, and 524 are separated by the epoxy resin, which can reduce the electrical leakage (and increase the resistance) through the metal particles. For example, there can be a leakage current path 535 between metal interconnects 534 and 536 through metal particles 510, 512, and 514, and a leakage current path 542 between metal interconnects 544 and 546 through metal particles 520, 522, and 524. But because the metal particles are separated by the epoxy resin, which has a relatively high breakdown voltage (e.g., compared with air), both leakage current path can have high resistance, and very little leakage current can flow between the metal interconnects through the metal particles and the epoxy resin.

However, the dicing operation may remove some of the resin on diced surfaces 502 and 504, which may expose the metal particles on the diced surfaces and reduce the resistance of the leakage current path through those metal particles. For example, metal particles 526 and 528 on diced surface 502 and metal particles 530 and 532 on diced surface 504 may be exposed by the removal of epoxy resin 533. Accordingly, part of metal particles 526 and 528 can be separated by an air gap 550, and part of metal particles 530 and 532 can be separated by an air gap 552. Because the air can have a lower breakdown voltage than the epoxy resin, the metal particles exposed on the diced surfaces 502/504 can provide a leakage current path with reduced resistance. For example, referring to FIG. 5C, there can be a leakage current path 560 with reduced resistance between metal interconnects 562 and 564 and through metal particles 566, 532, 530, 568, 570, 572, and 574 and the air gaps between those metal particles, leading to potential electrical shorts and compromising the functionality, reliability, and safety of semiconductor package 200.

FIG. 6A and FIG. 6B illustrate a semiconductor package 300 including example MMC materials that can address at least some of the issues described above with respect to semiconductor package 200. Semiconductor package 300 is substantially similar to semiconductor package 200, except some or all of the metal particles of the MMC material can be coated metal particles. In all other aspects, semiconductor package 300 is the same as semiconductor package 200. For brevity, additional details and variations included in the description of semiconductor package 200 are not repeated with respect to semiconductor package 300.

Referring to FIG. 6A and FIG. 6B, some or all of the metal particles of the MMC material can be coated metal particles, which are coated with an insulation layer 602, and the coated metal particles are suspended in epoxy resin 533. Insulation layer 602 includes a material that has a high breakdown voltage, such as silicon oxide (e.g., glass) or a metallic phosphate (e.g., iron phosphate). Insulation layer 602 can provide electrical insulation, which can add to the electrical insulation provided by epoxy resin 533 and increase the breakdown voltage of the MMC material. Also, for metal particles exposed on diced surfaces 502 and 504 and separated by air gaps (e.g., metal particles 526, 528, 530, and 532), insulation layer 602 can also add to the electrical insulation provided by the air gaps. Accordingly, a leakage current path through the exposed metal particles, such as leakage current path 560 between metal interconnects 562 and 564 in FIG. 6B, can have a high resistance, which can reduce potential electrical shorts and improve the functionality, reliability, and safety of semiconductor package 300 as compared to semiconductor package 200.

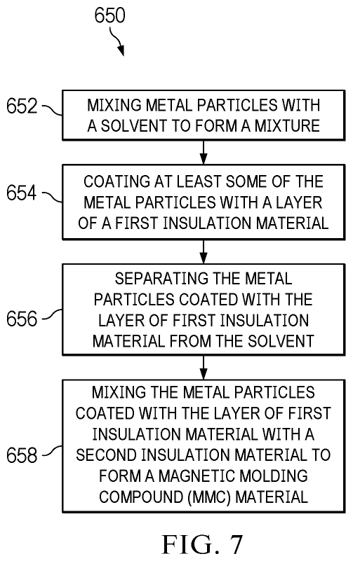

FIG. 7 illustrates a flowchart 650 of a method of creating the example MMC material of FIG. 6A and FIG. 6B. Referring to FIG. 7, in operation 652, metal particles (e.g., iron particles) can be mixed with a solvent to form a mixture. The solvent may be water or an organic solvent (e.g., alcohol, and kerosene). Mixing and stirring the metal particles and solvent creates a viscous slurry 1006, in which the metal particles are suspended in solvent.

In operation 654, at least some of the metal particles can be coated with a layer of an insulation material (e.g., insulation layer 602). Examples of the first insulation material includes silicon dioxide and phosphate. A reagent 1008 is added to the slurry, followed by heated and stirred to form the insulation layer on the metal particles.

In some examples, the reagent creates X—OH or X—OR bond to coat an insulation layer on the surface of metal particles 1002, where X represents Si (silicon) or P (phosphorus), OH represents Hydroxide, and R represents an alkyl substituent. Different reagents 1008 can be used to coat different insulation materials on metal particles 1002. For example, to coat a layer of silicon dioxide on metal particles 1002, a reagent including an orthosilicate, such as tetraethyl orthosilicate (Si(OC₂H₅)₄), can be used in operation 654. Also, to coat a layer of phosphate on metal particles 1002, a reagent including a phosphoric acid, such as orthophosphoric acid (H₃PO₄), can be used in operation 654.

In operation 656, the metal particles coated with the insulation layer can be separated from the solvent. The separation can be performed by, for example, passing slurry 1006 through a filter to remove solvent 1004 and reagent 1008 while retaining the metal particles, followed by washing and drying the metal particles.

In operation 656, the metal particles coated with the insulation layer can be mixed with a second insulation material to form a magnetic molding compound (MMC) material. The second insulation material includes epoxy resin. As part of operation 656, the metal particles can be mixed with epoxy resin, followed by a kneading operation in which the mixture can be kneaded with an extruder. The kneaded mixture can be made into a particular shape (e.g., a sheet) and cooled. The MMC material can then be crushed into particles, which can be melted and molded to form mold compound 208.

FIG. 8 illustrates a semiconductor package 400 with another design that addresses at least some of the issues described above with respect to semiconductor package 200. Semiconductor package 400 is substantially similar to semiconductor package 200, except exposed surfaces of the MMC material are coated with an insulation coating layer 802. In all other aspects, semiconductor package 400 is the same as semiconductor package 200. For brevity, additional details and variations included in the description of semiconductor package 200 are not repeated with respect to semiconductor package 400.

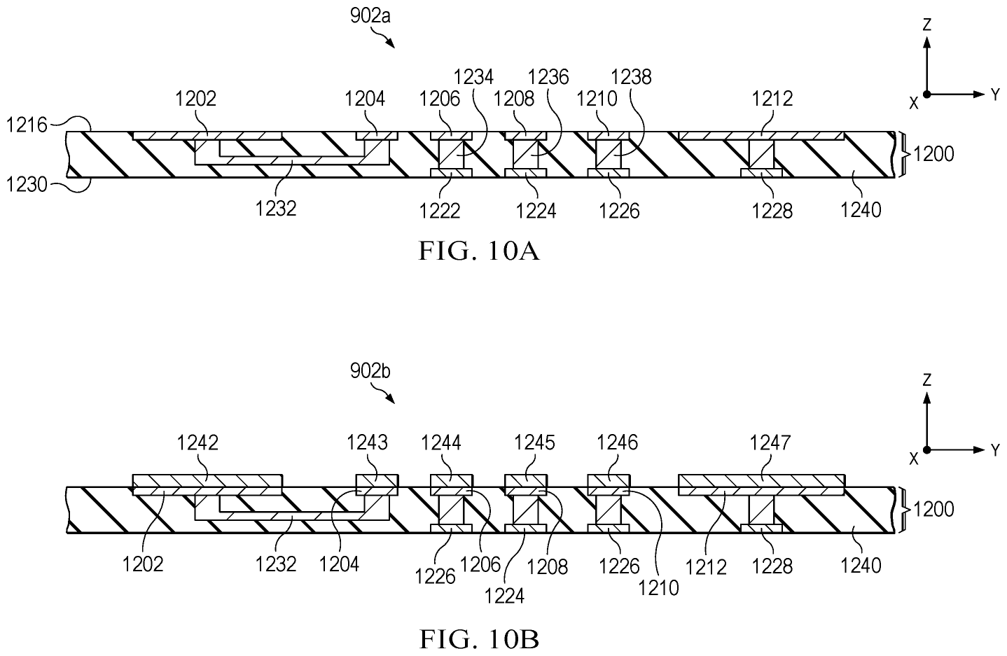

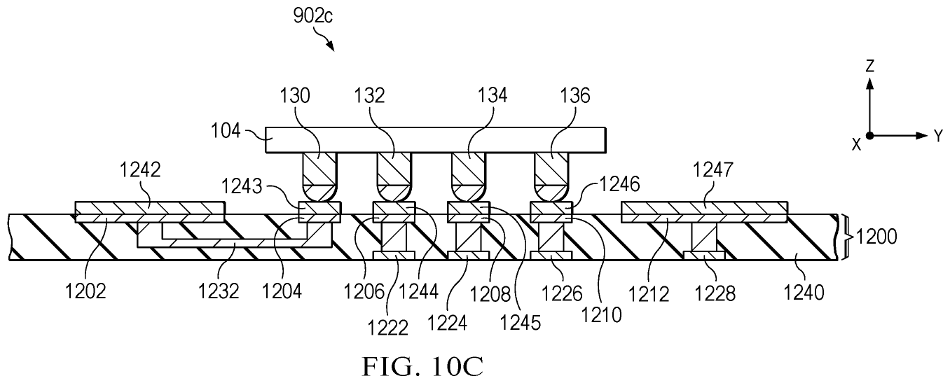

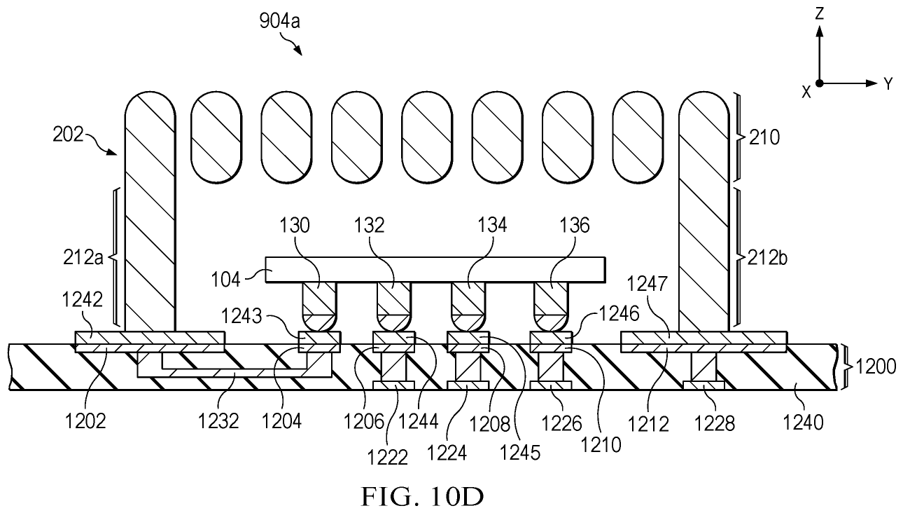

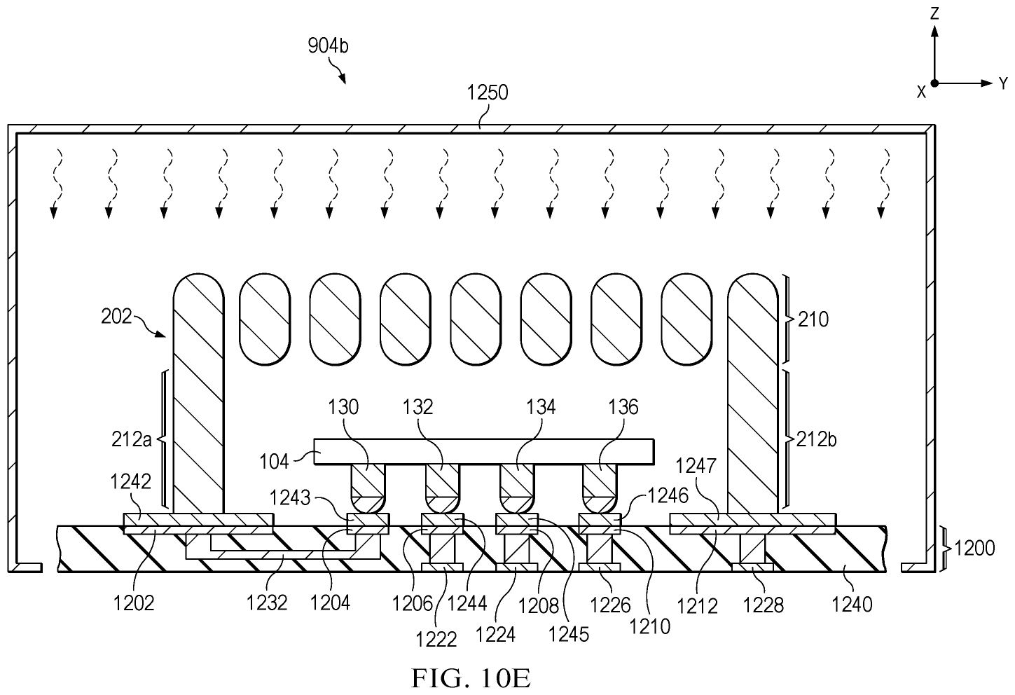

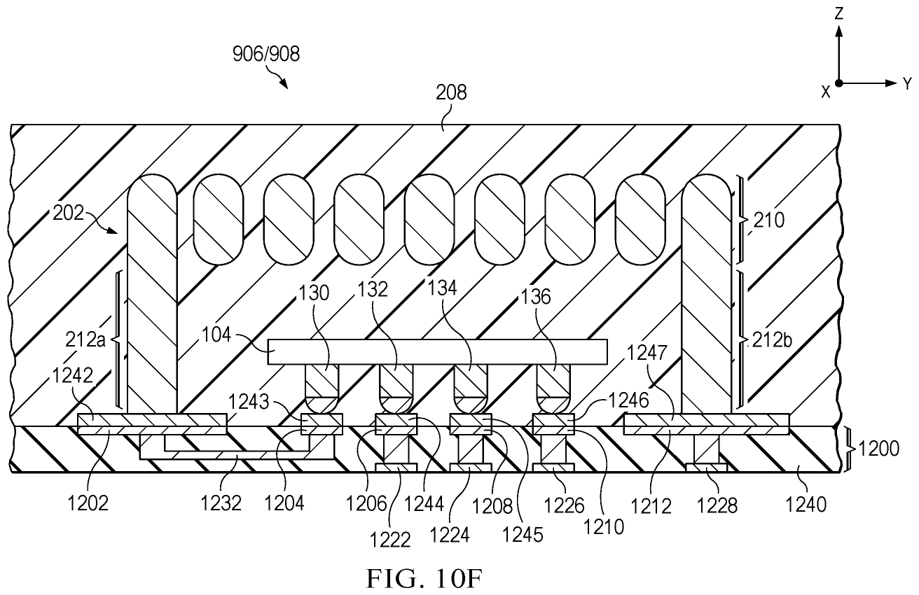

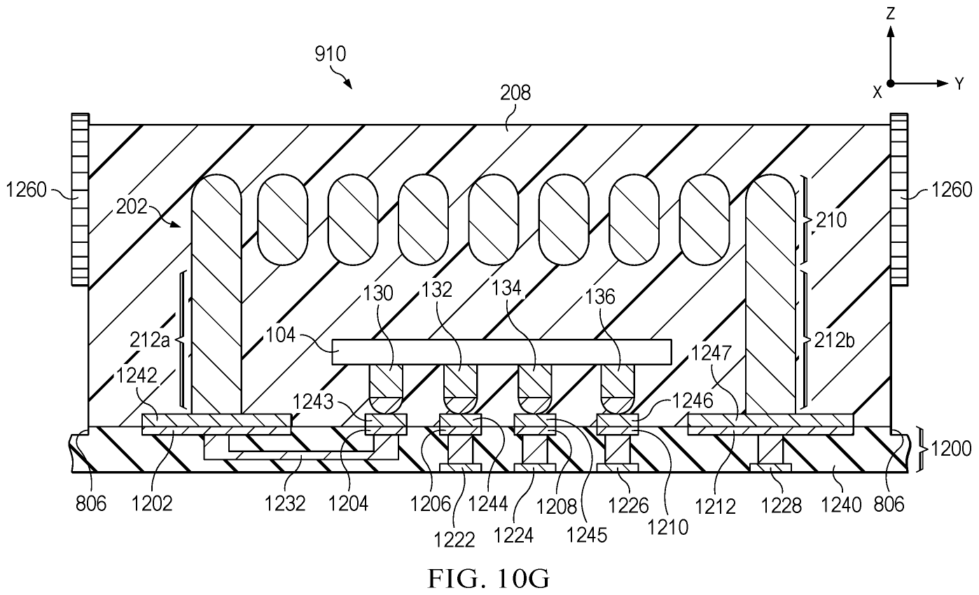

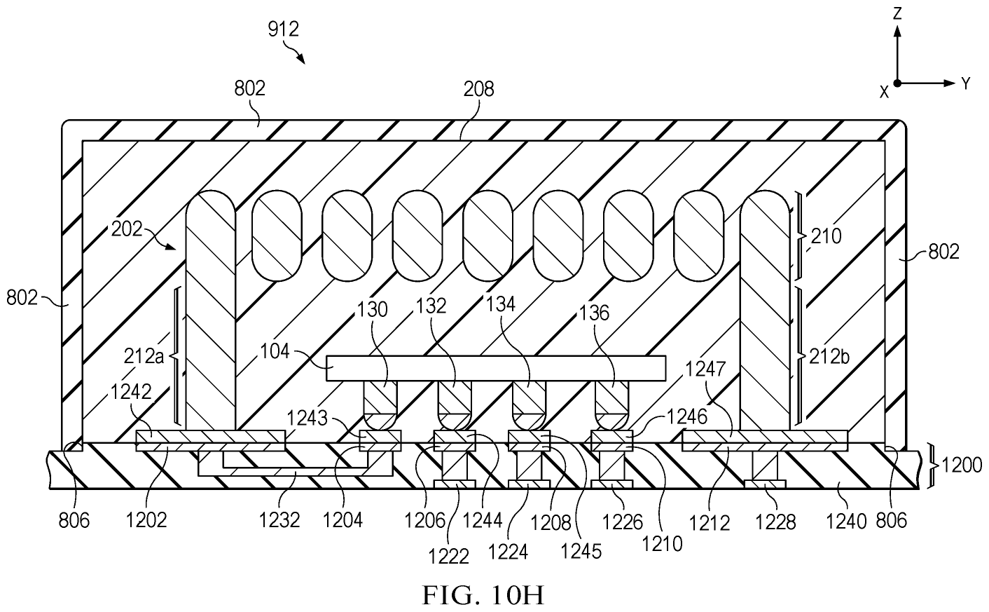

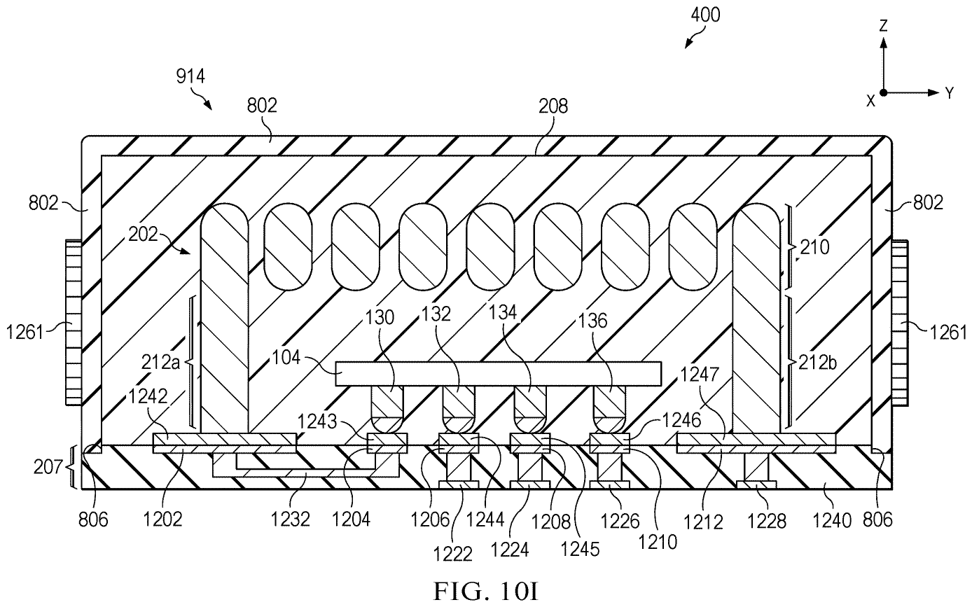

The coating layer 802 covers the exposed surfaces of the MMC material, including the surface of the MMC material, such as metal particles 526, 528, 530, and 532. The coating layer 802 mitigates leakage current through exposed metal particles on the surfaces of the MMC. The coating layer 802 is substantially free of metal particles. Substantially free of metal particles means without metal particles that would substantially impact the functionality of the coating layer 802 as an insulation layer over the MMC. In this manner, preferred examples of the coating layer 802 include no added metal particles to commercially available nonmagnetic insulation layers. As described with respect to FIG. 10G, substrate 207 includes a notch from a partial cut to expose the MMC material' the notch representing a stepped side surface 806 in substrate 207 of package 400.

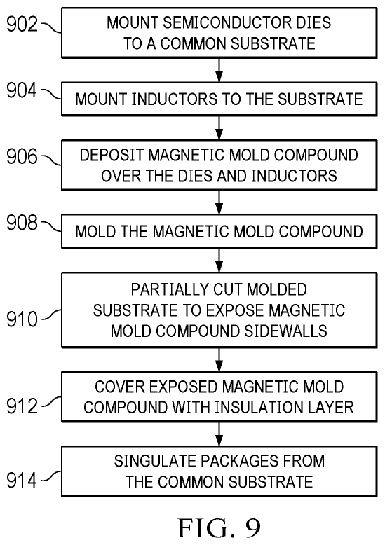

In a variation of semiconductor package 400, some or all of the metal particles of the MMC material can be coated metal particles, as described with respect to semiconductor package 300. The coated metal particles mitigate leakage current path within the MMC as described with respect to a leakage current path 542 of FIG. 5B. The functionality of coated metal particles may be combined with mitigating leakage current through exposed metal particles on the surfaces of the MMC as provided by insulation layer 802. Further details of semiconductor package 400 are provided with respect to FIG. 9, and FIGS. 10A-10I.

FIG. 9, and FIGS. 10A-10I illustrate examples of a method of fabricating a semiconductor die with an insulation layer covering a MMC, such as semiconductor package 400 of FIG. 8. FIG. 9 illustrates a flowchart 900 of an example method of fabricating the semiconductor die, and FIGS. 10A-10C are schematic diagrams illustrating various operations of the example method of FIG. 9.

In operation 902, multiple semiconductor dies can be mounted on a substrate, such as a conventional leadframe or routable leadframe.

Referring to FIG. 10A, in sub-operation 902a, a common substrate 1200 includes metal pads 1202, 1204, 1206, 1208, 1210, 1212 on surface 1216 and metal pads 1222, 1224, 1226, and 1228 on surface 1230 opposite to surface 1216. Common substrate 1200 also includes metal interconnects 1232, 1234, 1236, and 1238 to provide electrical connection between the metal pads. Common substrate 1200 also includes an insulation layer 1240, such as a polymer, ABF, or a ceramic material, to provide electrical insulation among the metal interconnects and the metal pads. In some examples, common substrate 1200 includes a routable lead frame (RLF).

Also, referring to FIG. 10B, in sub-operation 902b, solder layers 1242, 1243, 1244, 1245, 1246, and 1247 are deposited on respective metal pads 1202, 1204, 1208, 1210, and 1212.

Further, referring to FIG. 10C, in sub-operation 902c, semiconductor dies 104 can be mounted to metal pads 1243 through 1246 of common substrate 1200 via metal interconnects 130 through 136. In some examples, a pick-and-place (PnP) machine can align metal interconnects 130 through 136 with respective solder layers 1243 through 1246, and then place semiconductor dies 104 onto the solder layers.

Referring again to FIG. 9, in operation 904, multiple inductors can be mounted on the substrate.

Referring to FIG. 10D, in sub-operation 904a, stilt portions 212a and 212b of inductor 202 can be mounted to metal pads 1202 and 1212 of common substrate 1200 via respective solder layers 1242 and 1247, such that coil portion 210 of inductor 202 is on/over semiconductor die 104. In some examples, a PnP machine can align stilt portions 212a and 212b of inductor 202 with respective solder layers 1242 and 1247, and then place the stilt portions onto the solder layers. Also, referring to FIG. 10E, in sub-operation 904b, a reflow operation can be performed, in which inductors 202 and semiconductor dies 104, together with common substrate 1200 and the solder layers 1242 through 1247, are heated in an oven 1250. The solder layers can reflow in a molten state to create solder joints between inductors 202 and semiconductor dies 104 and common substrate 1200.

Referring to FIG. 9 and FIG. 10F, in operation 906, a magnetic material (e.g., MMC) is deposited on the semiconductor dies, the inductors, and the substrate. The magnetic material includes coated metal particles, which are coated with a first insulation material; and a second insulation material, in which the coated metal particles are suspended. Example of the magnetic material are illustrated in FIGS. 6A-8. The magnetic material optionally includes coated metal particles, such as metal particles 510, 512, 514, 520, 522, and 524 of FIGS. 6A-8, where each coated metal particle is coated with insulation layer 602 such as silicon dioxide/phosphate layer, and the coated metal particles are suspended in epoxy resin, to reduce leakage on the diced surface where the epoxy resin may be removed and metal particles may be exposed. Also, in operation 908, the magnetic material can be molded and heated, such that the magnetic material can be hardened to form mold compound 208 for respective semiconductor dies 104 and inductors 202. Following the molding operation, the semiconductor dies 104 and inductors 102 for an array of packages are encapsulated on the common substrate 1200 by mold compound 208.

Referring to FIG. 9 and FIG. 10G, in operation 910, the magnetic mold compound 208 and the common substrate 1200 are partially cut to form grooves between adjacent semiconductor dies 104 and expose sidewalls of the magnetic mold compound 208 for individual semiconductor packages on the common substrate 1200, each individual semiconductor package including respective semiconductor dies 104 and inductors 102. The dicing can be performed by, for example, a rotary blade 1260. The partial cut preferably extends all the way through magnetic mold compound 208 and optionally includes a partial cut into the common substrate 1200, although the substrate 1200 remains intact to facilitate bulk coating of insulation layer 802 on exposed surfaces of the magnetic mold compound 208 prior to singulation. Partially cutting the common substrate 1200 provides a tolerance to ensure the partial cut preferably extends all the way through magnetic mold compound 208.

In some examples, the partial cutting can be performed to remove some of the metal particles from the magnetic material to create cavities, which can be filled with air or another insulation material such as epoxy resin. Removal of metal particles can be performed by increasing the contact time between the metal particles and the blade during the dicing operation. The contact time can be increased by decreasing the speed at which the blade moves across the dicing surface (e.g., the dicing speed), decreasing the rotation speed of the blade (e.g., the spindle speed), or both, so that the force exerted by the blade on the metal particles can overcome the bonding force between the metal particles and the epoxy resin.

Referring to FIG. 9 and FIG. 10H, in operation 912, after the partial cutting operation, coating insulation layer 802 is applied to cover exposed surfaces of the magnetic mold compound 208. The coating insulation layer 802 is an insulation material that covers the dicing surface to fill any cavities remaining from removed metal particles. In some examples, the coating insulation layer 802 is applied by a spray or by a spin coating operation. In other examples, the coating insulation layer 802 may be formed by deposition, such as chemical vapor deposition. In other examples, the coating insulation layer 802 may be formed by overmolding coating insulation layer 802, a process which may substantially fill the partial cuts between the individual semiconductor packages on the common substrate 1200. In such an example, package singulation would include cutting the coating insulation layer 802 between individual packages 400.

In some examples, covering exposed surfaces of the magnetic material with the coating insulation layer 802 includes molding the coating insulation layer 802 over the exposed surfaces of the magnetic material, such that the coating insulation layer 802 is an overmold. In such examples, the coating insulation layer 802 resin may include epoxy resins, such as an epoxy-based thermoset polymer, polyurethane resins, and/or silicone resins. The resin may further include, in addition to metal particles, one or more of the following: hardener, curing agent, fused silica, inorganic fillers, catalyst, flame retardants, stress modifiers, adhesion promoters, and other suitable components. Fillers, if any, may be selected to modify properties and characteristics of the resin base materials. Inert inorganic fillers may be selected to lower a coefficient of thermal expansion (to match magnetic mold compound 208), increase thermal conductivity (e.g., nonmetallic fillers, such as ceramic particles), and/or increase elastic modulus of mold compound 208 compared to the resin base. Particulate fillers may be selected to reduce strength characteristics such as tensile strength and flexural strength compared to the resin base materials.

In some examples, covering exposed surfaces of the magnetic material with the coating insulation layer 802 includes depositing the coating insulation layer 802 on the exposed surfaces of the magnetic material. Deposition may occur through spray, vapor deposition and/or chemical deposition. In various examples, the deposition may result in a coating thickness in the range of in the range of 3 to 25 micrometers (μm), such as in the range of 5 to 10 μm on the top and all sides of magnetic mold compound 208. Suitable deposition coatings for insulation layer 802 suitable include parylene coatings, glass coatings, polyimide coatings, cured epoxy resin; such as a cured photosensitive film, such as TMMR NA1000®, available from Tokyo Ohka Kogyo Co. LTD of Kawasaki, Kanagawa, Japan, a silicone-based compound; such as SINR-2101®, available from Shin-Etsu Chemical of Tokyo, Japan, a maleimide imide resin; such as SF-Resin®, available from Showa Denko America, Inc. of New York, New York, U.S.A, and/or a fluoropolymer; such as polytetrafluoroethylene.

Referring to FIG. 9 and FIG. 10I, in operation 914, after completing the partial cut of the molded common substrate 1200 to form a wide groove in the between individual semiconductor packages 400 on the common substrate 1200, another dicing stage is performed, for example using a narrow rotary saw blade 1261 or stealth laser dicing and cool expansion, to separate each semiconductor package 400 from adjacent semiconductor packages 400 while leaving coating insulation layer 802 over the sidewalls of the magnetic mold compound 208 in each package. This results in the singularized (i.e. segmented, separated) semiconductor packages 400, including singulated substrates 207 with stepped side surfaces 806 as depicted in FIG. 10I.

In some examples, the rotary blade 1261 may have a smaller width than the rotary blade 1260. This allows rotary blade 1261 to cut the common substrate 1200 to without removing the insulating layer 802 from the sidewalls of the magnetic mold compound. For example, the rotary blade 1260 may have a width of 80 μm, while the rotary blade 1261 has a width of 52 μm. Such a blade combination would result in a stepped surface 806 width in the range of 11 to 17 μm. As another example, the singulation of FIG. 10I may occur using a stealth laser dicing and cool expansion. Stealth laser dicing and cool expansion does not remove the material, meaning the width of the stepped surface 806 would be about half of the width of the saw blade used to form the partial cut of FIG. 10G, resulting in a stepped surface 806 width in the range of 30 to 50 μm for a blade 1260 width of 80 μm, or a stepped surface 806 width in the range of 20 to 32 μm for a blade 1260 width of 52 μm. Other dimensions are also possible based on the partial cut and singulation techniques. If the dicing operation removes a portion of the coating insulation layer 802, the thickness of coating insulation layer 802 covering the sidewalls of the magnetic mold compound 208 following dicing may be the same as the side stepped surface 806 width. In some examples, the coating insulation layer 802 may be too thin to be affected by the dicing operation. In such examples, the thickness of the coating insulation layer 802 remains the same during the dicing operation.

Any of the methods described herein may be totally or partially performed with a computing system including one or more processors configured to perform the steps. Thus, embodiments are directed to computing systems configured to perform the steps of any of the methods described herein, potentially with different components performing respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. A semiconductor package comprising:
a substrate;
a semiconductor die;
metal interconnects, the semiconductor die being mounted to the substrate via the metal interconnects;
an inductor mounted to the substrate;
a magnetic material encapsulating the semiconductor die, the inductor, and the metal interconnects, the magnetic material including metal particles suspended in a first insulation material; and
a second insulation material covering the magnetic material, wherein the second insulation material is substantially free of metal particles.

2. The semiconductor package of claim 1, wherein the first insulation material includes an epoxy resin.

3. The semiconductor package of claim 1, wherein the second insulation material is a deposition.

4. The semiconductor package of claim 3, wherein the deposition selected from a group consisting of:
a parylene;
a glass;
a polyimide;
a cured epoxy resin;
a silicone-based compound;
a maleimide imide resin; and
a fluoropolymer.

5. The semiconductor package of claim 1, wherein the second insulation material is an overmold.

6. The semiconductor package of claim 5, wherein the second insulation material includes an epoxy resin.

7. The semiconductor package of claim 1, wherein the metal particles are coated with a third insulation material.

8. The semiconductor package of claim 7, wherein the third insulation material includes one of a group consisting of:
a silicon oxide material; and
a phosphate material.

9. The semiconductor package of claim 1, wherein the inductor includes a coil portion and a stilt portion, the stilt portion coupled to the substrate.

10. The semiconductor package of claim 9, wherein the coil portion is over the semiconductor die.

11. The semiconductor package of claim 9, further comprising a capacitor encapsulated in the magnetic material,
wherein the coil portion is over the capacitor.

12. The semiconductor package of claim 1, wherein the metal interconnects are first metal interconnects, and the substrate includes:
first metal pads on a first side of the substrate, the first metal pads coupled to the first metal interconnects and to the inductor;
second metal pads on a second side of the substrate opposite to the first side;
an insulation layer between the first side and the second side; and
second metal interconnects in the insulation layer and coupled between the first metal pads and the second metal pads.

13. The semiconductor package of claim 12, wherein:
the first metal pads and the second metal interconnects include a copper metal;
the second metal pads include at least one of a palladium metal or a silver metal; and
the insulation layer includes at least one of: a polymer material, an Ajinomoto Build-up Film, or a ceramic material.

14. The semiconductor package of claim 13, further comprising a solder resist layer on the second side.

15. The semiconductor package of claim 1, wherein the substrate is a routable leadframe.

16. A method comprising:
mounting semiconductor dies to a substrate;
mounting inductors to the substrate;
molding a magnetic material over the semiconductor dies and the inductors, the magnetic material including metal particles suspended in a first insulation material;
cutting the magnetic material to form grooves between adjacent semiconductor dies, wherein the substrate remains intact subsequent to cutting the magnetic material;
covering exposed surfaces of the magnetic material with a second insulation material; and
dicing the substrate to form semiconductor packages including respective semiconductor dies and inductors.

17. The method of claim 16, wherein the first insulation material includes an epoxy resin.

18. The method of claim 16, wherein covering the exposed surfaces of the magnetic material with the second insulation material comprises depositing the second insulation material on the exposed surfaces of the magnetic material.

19. The method of claim 18, wherein the second insulation material is selected from a group consisting of:
a parylene;
a glass;
a polyimide;
a photosensitive film;
a silicone-based compound;
a maleimide imide resin; and
a fluoropolymer.

20. The method of claim 16, wherein covering the exposed surfaces of the magnetic material with the second insulation material comprises molding the second insulation material over the exposed surfaces of the magnetic material.

21. The method of claim 19, wherein the second insulation material includes an epoxy resin.

22. The method of claim 16, wherein:
the inductors include a coil portion and a stilt portion; and
mounting the inductors to the substrate includes coupling the stilt portions to the substrate.

23. The method of claim 22, further comprising mounting capacitors to the substrate, wherein mounting the inductors to the substrate includes mounting the inductors to the substrate such that the coil portions are over the capacitors.
